(19) United States
(12) Patent Application Publication
(10) Pub. No.: US 2019/0067014 A1
(43) Pub. Date: Feb. 28, 2019

(54) METHODS FOR FILLING A GAP FEATURE ON A SUBSTRATE SURFACE AND RELATED SEMICONDUCTOR DEVICE STRUCTURES

(71) Applicant: ASM IP Holding B.V., Almere (NL)

(72) Inventors: Kiran Shrestha, Phoenix, AZ (US); Bhushan Zope, Phoenix, AZ (US); Shankar Swaminathan, Phoenix, AZ (US); Chiyu Zhu, Helsinki (FI); Henri Tuomas Antero Jussila, Espoo (FI); Qi Xie, Leuven (BE)

(21) Appl. No.: 16/105,761

(22) Filed: Aug. 20, 2018

Related U.S. Application Data
(63) Continuation-in-part of application No. 15/691,241, filed on Aug. 30, 2017.
(60) Provisional application No. 62/607,070, filed on Dec. 18, 2017.
(60) Provisional application No. 62/619,579, filed on Jan. 19, 2018.

(51) Int. Cl. H01L 21/285; H01L 21/3213; H01L 23/532; C23C 16/14; C23C 16/455

(52) U.S. Cl. CPC H01L 21/28556; H01L 21/28568; C23C 16/45553; H01L 23/53257; C23C 16/14; H01L 21/32135

(57) ABSTRACT

Methods for filling a gap feature on a substrate surface are disclosure. The methods may include: providing a substrate comprising one or more gap features into a reaction chamber; and partially filling the one or more gap features with a molybdenum metal film by a cyclical deposition-etch process, wherein a unit cycle of the cyclical deposition-etch process comprises: partially filling the one or more gap features with a molybdenum metal film by a performing at least one unit cycle of a first cyclical deposition process; and partially etching the molybdenum metal film. The methods may also include: filling the one or more gap features with molybdenum metal film by performing at least one unit cycle of a second cyclical deposition process. Semiconductor device structures including a gap fill molybdenum metal film disposed in one or more gap features in or on a surface of a substrate formed by the methods of the disclosure are also disclosed.

### CROSS-REFERENCE TO RELATED APPLICATION

The present application claims priority to: U.S. Non-Provisional patent application Ser. No. 15/691,241, entitled “Layer Forming Method” and filed on Aug. 30, 2017; U.S. Provisional Patent Application No. 62/607,070, entitled “Layer Forming Method” and filed on Dec. 18, 2017; and U.S. Provisional Patent Application No. 62/619,579, entitled “Deposition Method” and filed on Jan. 19, 2018.

### FIELD OF INVENTION

The present disclosure relates generally to methods for filling a gap feature on a substrate surface and particularly methods for filling one or more gap features with a molybdenum metal film utilizing a cyclical deposition-etch process. The present disclosure also generally relates to semiconductor device structures including one or more gap features filled with a molybdenum metal film.

### BACKGROUND OF THE DISCLOSURE

Semiconductor fabrication processes for forming semiconductor device structures, such as, for example, transistors, memory elements, and integrated circuits, are wide ranging and may include deposition processes, etch processes, thermal annealing processes, lithography processes, and doping processes, amongst others.

A particular semiconductor fabrication process commonly utilized is the deposition of a metal film into a gap feature thereby filling the gap feature with the metal film, a process commonly referred to as “gap fill.” Semiconductor substrates may comprise a multitude of gap features on a substrate with a non-planar surface. The gap features may comprise substantially vertical gap features being disposed between protruding portions of the substrate surface or indentations formed in a substrate surface. The gap features may also comprise substantially horizontal gap features being disposed between two adjacent materials bounding the horizontal gap feature. As semiconductor device structure geometries have decreased and high aspect ratio features have become more common place in such semiconductor device structures as DRAM, flash memory, and logic, it has become increasingly difficult to fill the multitude of gap features with a metal having the desired characteristics.

Deposition methods such as high density plasma (HDP), sub-atmospheric chemical vapor deposition (SACVD), and low pressure chemical vapor deposition (LPCVD) have been used for gap fill processes, but these processes commonly do not achieve the desired gap fill capability.

Accordingly, methods and associated semiconductor device structures are desired for filling gap features on a non-planar substrate with a gap fill metal with improved characteristics.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, methods for filling a gap feature on a substrate surface are provided. The methods may comprise: providing a substrate comprising one or more gap features into a reaction chamber; partially filing the one or more gap features with a molybdenum metal film by a cyclical deposition-etch process, wherein a unit cycle of the cyclical deposition-etch process comprises: partially filing the one or more gap features with a molybdenum metal film by performing at least one unit cycle of a first cyclical deposition process; and partially etching the molybdenum metal film. The methods may also include: filling the one or more gap features with a molybdenum metal film by performing at least one unit cycle of a second cyclical deposition process.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIGS. 1A and 1B illustrate cross-sectional schematic diagrams of gap features filled with a metal gap fill material wherein the metal gap-fill material includes a seam feature;

FIG. 2 illustrates a non-limiting exemplary process flow, demonstrating a method for filing one or more gap features on a surface of a substrate with a molybdenum metal film;

FIG. 3 illustrates a non-limiting exemplary sub-process flow, demonstrating a cyclical deposition process for depositing a molybdenum metal film in a gap feature according to the embodiments of the disclosure; and

FIGS. 4A and 4B illustrate cross-sectional schematic diagrams of semiconductor device structures that include a molybdenum metal film disposed in and filling one or more gap features according to the embodiments of the disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

As used herein, the term “substrate” may refer to any underlying material or materials that may be used, or upon which, a device, a circuit, or a film may be formed.

As used herein, the term “cyclic deposition” may refer to the sequential introduction of one or more precursors (reactants) into a reaction chamber to deposit a film over a substrate and includes deposition techniques such as atomic layer deposition and cyclical chemical vapor deposition.

As used herein, the term “cyclical chemical vapor deposition” may refer to any process wherein a substrate is sequentially exposed to one or more volatile precursors, which react and/or decompose on a substrate to produce a desired deposition.

As used herein, the term “atomic layer deposition” (ALD) may refer to a vapor deposition process in which deposition cycles, preferably a plurality of consecutive deposition cycles, are conducted in a reaction chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition,” “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “film” and “thin film” may refer to any continuous or non-continuous structures and material formed by the methods disclosed herein. For example, “film” and “thin film” could include 2D materials, nanolaminates, nanorods, nanotubes, or nanoparticles, or even partial or full molecular layers, or partial or full atomic layers or clusters of atoms and/or molecules. “Film” and “thin film” may comprise material or a layer with pinholes, but still be at least partially continuous.

As used herein, the term “molybdenum halide precursor” may refer to a reactant which comprises at least a molybdenum component and a halide component, wherein the halide component may include one or more of a chlorine component, an iodine component, or a bromine component.

As used herein, the term “molybdenum chalcogenide halide” may refer to a reactant which comprises at least a molybdenum component, a halide component, and a chalcogen component, wherein a chalcogen is an element from group IV of the periodic table including oxygen (O), sulphur (S), selenium (Se), and tellurium (Te).

As used herein, the term “molybdenum oxyhalide” may refer to a reactant which comprises at least a molybdenum component, an oxygen component, and a halide component.

As used herein, the term “reducing agent precursor” may refer to a reactant that donates an electron to another species in a redox chemical reaction.

As used herein, the term “crystalline film” may refer to a film which displays at least short range ordering or even long range ordering of the crystalline structure and includes single crystalline films as well as polycrystalline films.

As used herein, the term “gap feature” may refer to an opening or cavity disposed between two surfaces of a non-planar surface. The term “gap feature” may refer to an opening or cavity disposed between opposing inclined sidewalls of two protrusions extending vertically from the surface of the substrate or opposing inclined sidewalls of an indentation extending vertically into the surface of the substrate, such a gap feature may be referred to as a “vertical gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.”

As used herein, the term “seam” may refer to a line or one or more voids formed by the abutment of edges formed in a gap fill metal, and the “seam” can be confirmed using a scanning transmission electron microscopy (STEM) or transmission electron microscopy (TEM), wherein if observations reveals a clear vertical line or one or more vertical voids in a vertical gap fill metal, or a clear horizontal line or one or more horizontal voids in a horizontal gap fill metal, then a “seam” is present.

A number of example materials are given throughout the embodiments of the current disclosure, it should be noted that the chemical formulas given for each of the example materials should not be construed as limiting and that the non-limiting example materials given should not be limited by a given example stoichiometry.

The present disclosure includes methods for filling one or more gap features on a substrate surface and particularly methods for filling one or more gap features with a molybdenum metal film utilizing a cyclical deposition-etch process. Molybdenum metal thin films may be utilized in a number of applications, such as, for example, low electrical resistivity gap-fill, liner layers for 3D-NAND, DRAM word-line features, or as an interconnect material in CMOS logic applications. The ability to deposit a molybdenum metal film in a gap feature may allow for lower effective electrical resistivity for interconnects in logic applications, i.e., CMOS structures, and word-line/bit-line in memory applications, such as 3D-NAND and DRAM structures.

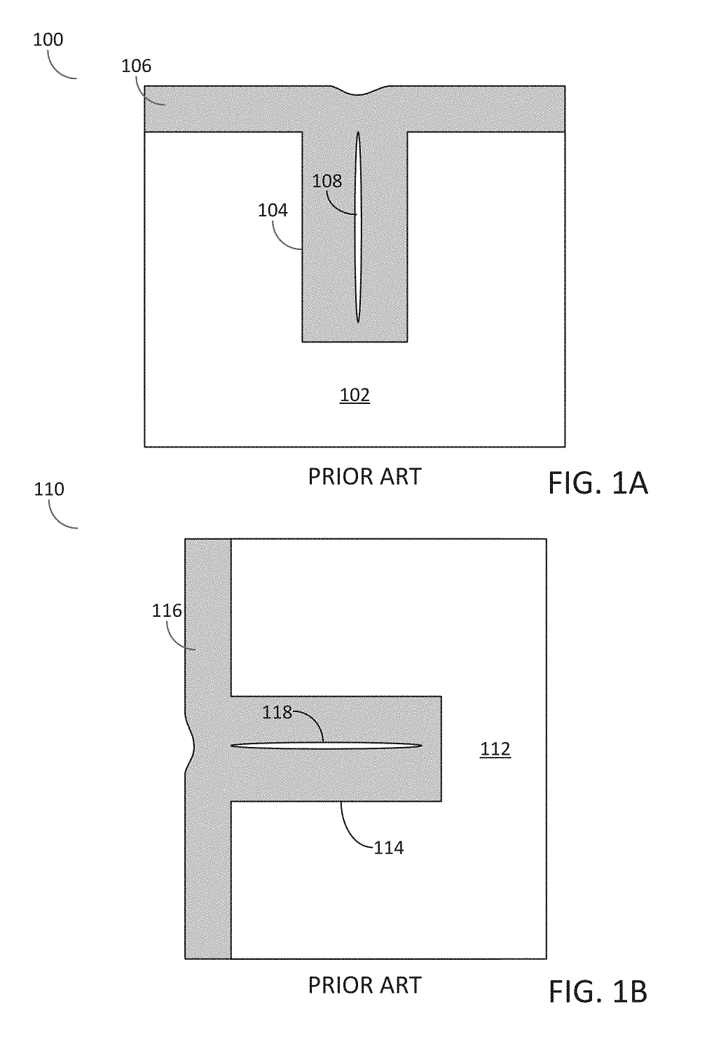

The embodiments of the disclosure may provide gap fill processes and gap fill metals which are superior to prior known methods. Examples of a semiconductor device structures including a gap feature filled with a metal film by common prior art methods are illustrated in FIG. 1A and FIG. 1B, wherein FIG. 1A illustrates a substantially vertical gap feature and associated gap fill metal and FIG. 1B illustrates a substantially horizontal gap feature and associated gap fill metal.

For example, FIG. 1A illustrates a cross-sectional view of a semiconductor device structure 100 comprising a substrate 102 including a substantially vertical gap feature 104, the substantially vertical gap feature 104 being filled with a metal gap fill material 106. As illustrated in FIG. 1A, disposed within the metal gap fill material 106 is a feature commonly referred to as a seam 108. A seam refers to a region in the metal gap fill material 106 where the edges of two films growing from both sidewalls of the gap feature touch each other, therefore the seam 108 is commonly disposed at the center of the gap feature 104. The formation of a seam 108 in the metal gap fill material is undesirable and may result in poor device performance and subsequent issues in semiconductor device fabrication processes. In this example, the seam 108 may comprise a vertical line or one or more macro-voids that may be observable using scanning transmission electron microscopy (STEM) or transmission electron microscopy (TEM) where, if observations reveal a vertical line or one or more macro-voids in the metal gap fill material 106, a seam 108 is present.

As an additional example, FIG. 1B illustrates a cross-sectional view of semiconductor device structure 110 comprising a substrate 112 including a substantially horizontal gap feature 114, the substantially horizontal gap feature 114 being filled with a metal gap fill material 116. As illustrates in FIG. 1B, disposed within the metal gap fill material 116 is a seam 118. Prior methods for filing a gap feature, such as exemplary horizontal gap feature 114, may include a preferential deposition of the metal gap fill material towards the entrance of the horizontal gap feature 114. This preferential deposition towards the entrance of the horizontal gap feature 114 may result in premature closure of the film proximate to the entrance of the horizontal gap feature 114, i.e., the two opposing faces may join proximate to the entrance of the horizontal gap feature prior to completely filing the horizontal gap feature with the metal film thereby resulting in the formation of the seam 118. Therefore, in this example, the seam 118 may comprise a horizontal line or one or more macro-voids that may be observable using scanning transmission electron microscopy (STEM) or transmission electron microscopy (TEM) where, if observations reveal a horizontal line or one or more macro-voids in the metal gap fill material 116, a seam 108 is present.

Accordingly, methods and related semiconductor device structures are desirable that enable the filling of one or more gap features, including both horizontal gap features and vertical gap features, with a metal gap fill material without the formation of a seam feature which may have a detrimental effect on device performance and device yield.

Therefore, the embodiments of the disclosure may include methods for filling a gap feature on a substrate surface. The methods may comprise: providing a substrate comprising one or more gap features into a reaction chamber; and partially filling the one or more gap features with a molybdenum metal film by a cyclical deposition-etch process, wherein a unit cycle of the cyclical deposition-etch process comprises: partially filing the one or more gap features with a molybdenum metal film by performing at least one unit cycle of a first cyclical deposition process; and partially etching the molybdenum metal film. The methods may also comprise; filling the one or more gap features by performing at least one unit cycle of a second cyclical deposition process.

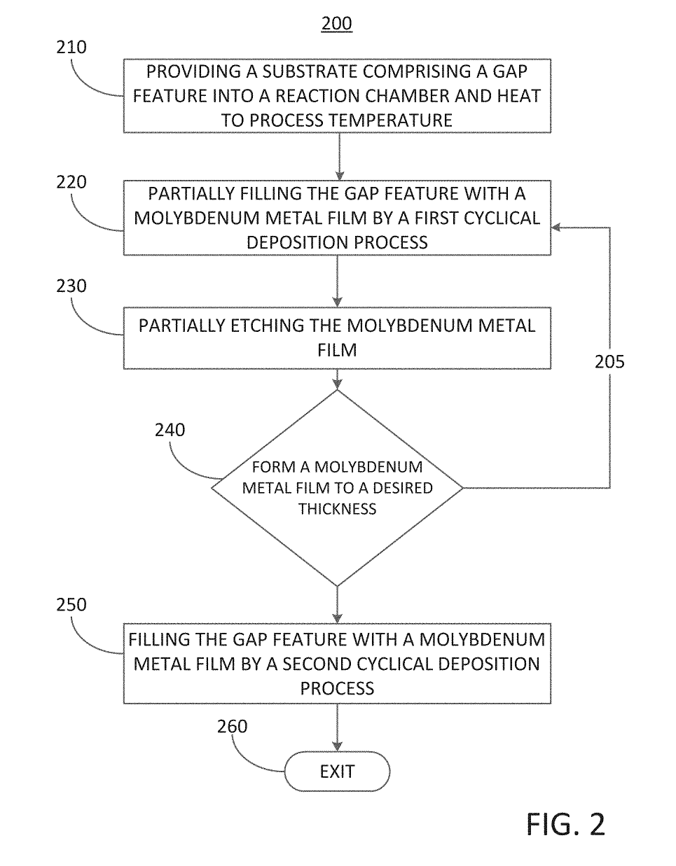

An exemplary process 200 for filling one or more gap features on or in a substrate is illustrated with reference to FIG. 2. The exemplary process 200 may comprise a cyclic deposition-etch phase 205 for partially filling the one or more gap features with a molybdenum metal film and a second cyclical deposition process for filling the one or more gap features, wherein the exemplary process 200 may be utilized to form a gap fill molybdenum metal film without the formation of a seam.

In more detail and with reference to FIG. 2, the exemplary gap fill process 200 may commence by means of a process block 210 which comprises providing a substrate comprising one or more gap features into a reaction chamber and heating the substrate to a desired process temperature.

In some embodiments of the disclosure, the substrate may comprise a patterned substrate including high aspect ratio features, such as, for example, trench structures, vertical gaps, horizontal gaps, and/or fin structures. For example, the substrate may comprise one or more substantially vertical gap features and/or one or more substantially horizontal gap features. The term “gap feature” may refer to an opening or cavity disposed between opposing inclined sidewalls of two protrusions extending vertically from the surface of the substrate or opposing inclined sidewalls of an indentation extending vertically into the surface of the substrate, such a gap feature may be referred to as a “vertical gap feature.” The term “gap feature” may also refer to an opening or cavity disposed between two opposing substantially horizontal surfaces, the horizontal surfaces bounding the horizontal opening or cavity; such a gap feature may be referred to as a “horizontal gap feature.” It should be noted that the embodiments of the disclosure are not limited to filling vertical gap features and/or horizontal gap features and that other geometries of gap features disposed in and/or on a substrate may be filled with a molybdenum metal by the processes disclosed herein.

In some embodiments of the disclosure, the substrate may comprise one or more substantially vertical gap features, wherein the vertical gap features may have an aspect ratio (height:width) which may be greater than 2:1, or greater than 5:1, or greater than 10:1, or greater than 25:1, or greater than 50:1, or even greater than 100:1, wherein “greater than” as used in this example refers to a greater distance in the height of the gap feature. In some embodiments of the disclosure, the substrate may comprise one or more substantially horizontal gap features, wherein the horizontal gap features may have an aspect ratio (height:width) which may be greater than 1:2, or greater than 1:5, or greater than 1:10, or greater than 1:25, or greater than 1:50, or even greater than 1:100, wherein “greater than” as used in this example refers to a greater distance in the width of the gap feature.

The substrate may comprise one or more materials and material surfaces including, but not limited to, semiconductor materials, dielectric materials, and metallic materials.

In some embodiments, the substrate may include semiconductor materials, such as, but not limited to, silicon (Si), germanium (Ge), germanium tin (GeSn), silicon germanium (SiGe), silicon germanium tin (SiGeSn), silicon carbide (SiC), or a group III-V semiconductor materials.

In some embodiments, the substrate may include metallic materials, such as, but not limited to, pure metals, metal nitrides, metal carbides, metal borides, and mixtures thereof.

In some embodiments, the substrate may include dielectric materials, such as, but not limited, to silicon containing dielectric materials and metal oxide dielectric materials. In some embodiments, the substrate may comprise one or more dielectric surfaces comprising a silicon containing dielectric material such as, but not limited to, silicon dioxide (SiO₂), silicon sub-oxides, silicon nitride (Si₃N₄), silicon oxynitride (SiON), silicon oxycarbide (SiOC), silicon oxycarbide nitride (SiOCN), silicon carbon nitride (SiCN). In some embodiments, the substrate may comprise one or more dielectric surfaces comprising a metal oxide such as, but not limited to, aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), and lanthanum oxide (La₂O₃).

In some embodiments of the disclosure, the substrate may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides, oxycarbides, oxycarbide nitrides, nitrides, or mixtures thereof.

Reactors or reaction chambers capable of being used to fill one or more gap features with a molybdenum metal film may configured for performing a cyclic deposition-etch process, wherein the deposition stages of the process may comprise a cyclic deposition process, such as, for example, atomic layer deposition or cyclical chemical vapor deposition. Therefore reactors or reaction chambers suitable for performing the embodiments of the disclosure may include ALD reactors, as well as CVD reactors, configured to provide the precursors. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers. In some embodiments in which a batch reactor is used, wafer-to-wafer non-uniformity is less than 3% (1 sigma), less than 2%, less than 1%, or even less than 0.5%.

The exemplary molybdenum metal film gap fill processes as described herein may optionally be carried out in a reactor or reaction chamber connected to a cluster tool. In a cluster tool, because each reaction chamber is dedicated to one type of process, the temperature of the reaction chamber in each module can be kept constant, which improves the throughput compared to a reactor in which the substrate is heated up to the process temperature before each run. Additionally, in a cluster tool it is possible to reduce the time to pump the reaction chamber to the desired process pressure levels between substrates. In some embodiments of the disclosure, the exemplary molybdenum metal film gap fill processes disclosed herein may be performed in a cluster tool comprising multiple reaction chambers, wherein each individual reaction chamber may be utilized to expose the substrate to an individual precursor gas and the substrate may be transferred between different reaction chambers for exposure to multiple precursors gases, the transfer of the substrate being performed under a controlled ambient to prevent oxidation/contamination of the substrate. For example, the cyclic deposition-etch processes described herein may comprise a deposition stage and an etch stage and a first reaction chamber associated with a cluster tool may be utilized for the deposition stage and a second reaction chamber associated with the same cluster tool may be utilized for the etch stage with the transfer back and forth between the first reaction chamber and second reaction chamber taking place under a controlled environment to prevent contamination or degradation of the substrate and associated metal films. In some embodiments of the disclosure, the molybdenum metal film gap fill processes of the current disclosure may be performed in a cluster tool comprising multiple reaction chambers, wherein each individual reaction chamber may be configured to heat the substrate to a different temperature.

In some embodiments, the gap fill processes of the current disclosure may be performed in a single stand-alone reactor which may be equipped with a load-lock. In that case, it is not necessary to cool down the reaction chamber between each run.

Once the substrate is disposed within a suitable reaction chamber, such as, for example, an atomic layer deposition reaction chamber or a chemical vapor deposition reaction chamber, the substrate may be heated to a desired process temperature. In some embodiments, the cyclical deposition-etch phase 205 of exemplary process 100 may be performed at a constant substrate temperature. In alternative embodiments, the substrate may be heated to a first substrate temperature for the deposition stage and a second substrate temperature for the etch stage of the cyclical deposition-etch phase 205.

In some embodiments of the disclosure, the substrate may be heated to a substrate temperature of less than approximately 800° C., or less than approximately 700° C., or less than approximately 600° C., or less than approximately 500° C., or less than approximately 400° C., or less than approximately 300° C., or even less than approximately 200° C. In some embodiments of the disclosure, the substrate temperature may be heated to a process temperature for exemplary process 200 of between 200° C. and 800° C., or between 300° C. and 700° C., or between 400° C. and 600° C., or between 525° C. and 575° C.

In addition, to achieving a desired process temperature, i.e., a desired substrate temperature, the exemplary gap fill process 200 may also regulate the pressure within the reaction chamber during the gap fill process 200 to obtain desirable characteristics of the gap fill process and the molybdenum metal film disposed within the one or more gap features. For example, in some embodiments of the disclosure, the exemplary gap fill process 200 may be performed within a reaction chamber regulated to a reaction chamber pressure of less than 300 Torr, or less than 200 Torr, or less than 100 Torr, or less than 50 Torr, or less than 25 Torr, or even less than 10 Torr. In some embodiments, the pressure within the reaction chamber during the exemplary gap fill process 200 may be regulated at a pressure between 10 Torr and 300 Torr, or between 20 Torr and 80 Torr, or between 40 Torr and 50 Torr, or even equal to or greater than 20 Torr.

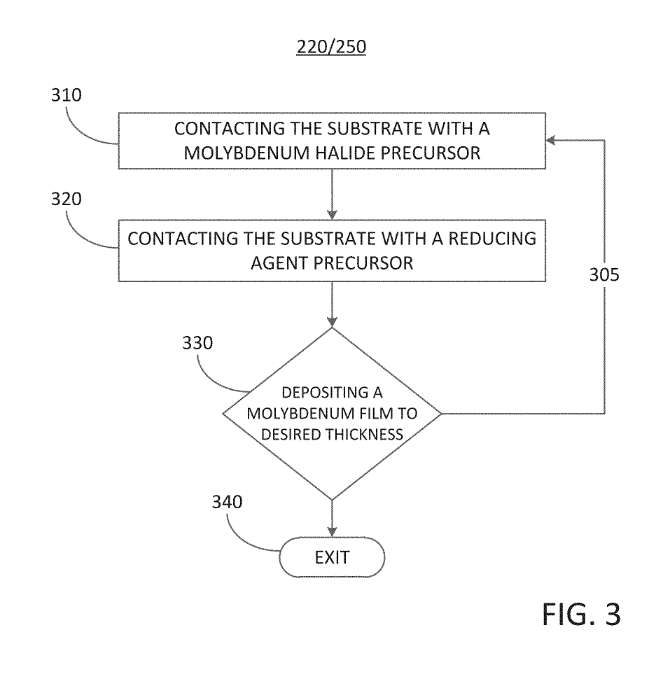

Once the substrate is heated to a desired process temperature and the pressure within the reaction chamber has been regulated to a desired level the exemplary gap fill process 100 may continue by means of cyclical deposition-etch phase 205. In some embodiments, the cyclical deposition-etch phase 205 may commence by means of a process block 220 comprising partially filing the one or more gap features with a molybdenum metal film by performing at least one unit cycle of a first cyclical deposition process. The process block 220 and its constituent sub-process blocks are described in more detail with reference to FIG. 3 which illustrates an exemplary cyclical deposition process for depositing a molybdenum metal film within the one or more gap features to partially fill the one or more gap features with a molybdenum metal film.

In more detail and with reference to FIG. 3, the process block 220 utilized for partially filing the one or more gap features with a molybdenum metal fill may comprise a first cyclical deposition process, such as, for example, an atomic layer deposition (ALD) process or a cyclical chemical vapor deposition (CCVD) process.

A non-limiting example embodiment of a cyclical deposition process may include atomic layer deposition (ALD), wherein ALD is based on typically self-limiting reactions, whereby sequential and alternating pulses of reactants are used to deposit about one atomic (or molecular) monolayer of material per deposition cycle. The deposition conditions and precursors are typically selected to provide self-saturating reactions, such that an absorbed layer of one reactant leaves a surface termination that is non-reactive with the gas phase reactants of the same reactants. The substrate is subsequently contacted with a different reactant that reacts with the previous termination to enable continued deposition. Thus, each cycle of alternated pulses typically leaves no more than about one monolayer of the desired material. However, as mentioned above, the skilled artisan will recognize that in one or more ALD cycles more than one monolayer of material may be deposited, for example, if some gas phase reactions occur despite the alternating nature of the process.

In an ALD-type process utilized for partially filling one or more gap features with a molybdenum metal film a unit deposition cycle may comprise exposing the substrate to a first vapor phase reactant, removing any unreacted first reactant and reaction byproducts from the reaction chamber, and exposing the substrate to a second vapor phase reactant, followed by a second removal step. In some embodiments of the disclosure, the first vapor phase reactant may comprise a molybdenum precursor and the second vapor phase reactant may comprise a reducing agent precursor.

Precursors may be separated by inert gases, such as argon (Ar) or nitrogen (N₂), to prevent gas-phase reactions between reactants and enable self-saturating surface reactions. In some embodiments, the inert gas used to prevent gas-phase reactants may consist of argon (Ar), wherein argon may be utilized to prevent nitridization of the surfaces of the one or more gap features. In some embodiments, however, the substrate may be moved to separately contact a first vapor phase reactant and a second vapor phase reactant. Because the reactions self-saturate, strict temperature control of the substrates and precise dosage control of the precursors may not be required. However, the substrate temperature is preferably such that an incident gas species does not condense into monolayers nor decompose on the surface. Surplus chemicals and reaction byproducts, if any, are removed from the substrate surface, such as by purging the reaction space or by moving the substrate, before the substrate is contacted with the next reactive chemical. Undesired gaseous molecules can be effectively expelled from a reaction space with the help of an inert purging gas. A vacuum pump may be used to assist in the purging.

According to some non-limiting embodiments of the disclosure, the process block 220 (FIG. 3) may comprise an ALD process utilized to partially fill the one or more gap features with a molybdenum metal film. In some embodiments of the disclosure, a unit ALD cycle may comprise two distinct deposition steps or stages. In a first stage of the deposition cycle (“the molybdenum stage”), the substrate surface on which deposition is desired may be contacted with a first vapor phase reactant comprising a molybdenum precursor which chemisorbs on to the surface of the substrate, forming no more than about one monolayer of reactant species on the surface of the substrate. In a second stage of the deposition the substrate surface on which deposition is desired may be contacted with a second vapor phase reactant comprising a reducing agent precursor (“the reducing stage”).

In more detail, FIG. 3 illustrates an exemplary molybdenum deposition process 220 for partially filing one or more gap feature with a molybdenum metal film and includes a cyclical deposition phase 305. The exemplary atomic layer deposition process 220 may commence with a sub-process block 310 which comprises contacting the substrate with a first vapor phase reactant and particularly, in some embodiments, contacting the substrate with a first vapor phase reactant comprising a molybdenum halide precursor, i.e., the molybdenum precursor.

In some embodiments of the disclosure, the molybdenum halide precursor may comprise a molybdenum chloride precursor, a molybdenum iodide precursor, or a molybdenum bromide precursor. In some embodiments, the molybdenum halide precursor may comprise a molybdenum chalcogenide and in particular embodiments the molybdenum chalcogenide precursor may comprise a molybdenum chalcogenide halide. For example, the molybdenum chalcogenide halide precursor may comprise a molybdenum oxyhalide selected from the group comprising: a molybdenum oxychloride, a molybdenum oxyiodide, or a molybdenum oxybromide. In particular embodiments of the disclosure, the molybdenum precursor may comprise a molybdenum oxychloride, including, but not limited to, molybdenum (IV) dichloride dioxide (MoO₂Cl₂).

In some embodiments of the disclosure, contacting the substrate with a first vapor phase reactant comprising a molybdenum halide precursor may comprise contacting the molybdenum halide precursor to the substrate for a time period of between about 0.1 seconds and about 60 seconds, between about 0.1 seconds and about 10 seconds, or between about 0.5 seconds and about 5.0 seconds, or even between 1.0 second and 2.0 seconds. In addition, during the contacting of the substrate with the molybdenum halide precursor, the flow rate of the molybdenum halide precursor may be less than 1000 sccm, or less than 500 sccm, or less than 100 sccm, or less than 10 sccm, or even less than 1 sccm. In addition, during the contacting of substrate with the molybdenum halide precursor the flow rate of the molybdenum precursor may range from about 1 to 2000 sccm, from about 5 to 1000 sccm, or from about 10 to about 500 sccm.

The exemplary atomic layer deposition process for partially filing one or more gap features with a molybdenum metal film as illustrated by exemplary process block 220 of FIG. 3 may continue by purging the reaction chamber. For example, excess first vapor phase reactant and reaction byproducts (if any) may be removed from the surface of the substrate, e.g., by pumping with an inert gas. In some embodiments of the disclosure, the purge process may comprise a purge cycle wherein the substrate surface is purged for a time period of less than approximately 5.0 seconds, or less than approximately 3.0 seconds, or even less than approximately 2.0 seconds. Excess first vapor phase reactant, such as, for example, excess molybdenum precursor and any possible reaction byproducts may be removed with the aid of a vacuum, generated by a pumping system in fluid communication with the reaction chamber.

Upon purging the reaction chamber with a purge cycle the exemplary atomic layer deposition process block 220 may continue with a second stage of the cyclical deposition phase 305 by means of a sub-process block 320 which comprises contacting the substrate with a second vapor phase reactant, and particularly contacting the substrate with a second vapor phase reactant comprising a reducing agent precursor (“the reducing precursor”).

In some embodiments of the disclosure, the reducing agent precursor may comprise at least one of forming gas (H₂+N₂), ammonia (NH₃), hydrazine (N₂H₄), an alkyl-hydrazine (e.g., tertiary butyl hydrazine (C₄H₁₂N₂)), molecular hydrogen (H₂), hydrogen atoms (H), a hydrogen plasma, hydrogen radicals, hydrogen excited species, an alcohol, an aldehyde, a carboxylic acid, a borane, or an amine. In further embodiments, the reducing agent precursor may comprise at least one of silane (SiH₄), disilane (Si₂H₆), trisilane (Si₃H₈), germane (GeH₄), digermane (Ge₂H₆), borane (BH₃), or diborane (B₂H₆). In particular embodiments of the disclosure, the reducing agent precursor may comprise molecular hydrogen (H₂).

In some embodiments of the disclosure, contacting the substrate with the reducing agent precursor may comprise contacting the substrate with the reducing agent precursor for a time period of between about 0.01 seconds and about 180 seconds, between about 0.05 seconds and about 60 seconds, or between about 0.1 seconds and about 30.0 seconds. In addition, during the contacting of the substrate with the reducing agent precursor substrate, the flow rate of the reducing agent precursor may be less than 30 slm, or less than 15 slm, or less than 10 slm, or less than 5 slm, or less than 1 slm, or even less than 0.1 slm. In addition, during the contacting of the substrate with the reducing agent precursor to the substrate the flow rate of the reducing agent precursor may range from about 0.1 to 30 slm, from about 5 to 15 slm, or equal to or greater than 10 slm.

Upon contacting the substrate with the reducing agent precursor, the exemplary process block 220 for at least partially filing one or more gap features with a molybdenum metal film may proceed by purging the reaction chamber. For example, excess reducing agent precursor and reaction byproducts (if any) may be removed from the surface of the substrate, e.g., by pumping whilst flowing an inert gas. In some embodiments of the disclosure, the purge process may comprise purging the substrate surface for a time period of between approximately 0.1 seconds and approximately 30 seconds, or between approximately 0.5 seconds and approximately 10 seconds, or even between approximately 1 second and 2 seconds.

Upon completion of the purge of the second vapor phase reactant, i.e., the reducing agent precursor (and any reaction byproducts) from the reaction chamber, the cyclic deposition phase 305 of exemplary atomic layer deposition process 220 may continue with a decision gate 340, wherein the decision gate 340 is dependent on the thickness of the molybdenum metal film deposited in the one or more gap features. For example, the embodiments of the disclosure may utilize a cyclic deposition-etch process to partially fill the one or more gap features therefore the thickness of the molybdenum film deposited within the one or more gap features should be less than the thickness that may cause premature closure of the gap feature at the entrance to the gap feature as this may result in the formation of an unwanted seam. For example, if the molybdenum metal film is deposited at an insufficient thickness for a desired gap feature geometry, then the cyclical deposition phase 305 may be repeated by returning to the sub-process block 310 and continuing through a further deposition cycle, wherein a unit deposition cycle may comprise contacting the substrate with a molybdenum halide precursor (sub-process block 310), purging the reaction chamber, contacting the substrate with a reducing agent precursor (sub-process block 320), and again purging the reaction chamber. A unit deposition cycle of cyclical deposition phase 305 may be repeated one or more times until a desired thickness of a molybdenum metal film is deposited within the one or more gap features thereby partially filling the one or more gap features. The desired thickness of the molybdenum metal film deposited within the one or more gap features may therefore be dependent on the aspect ratio of the gap feature to be filled. Once the molybdenum metal film has been deposited to the desired thickness the exemplary atomic layer deposition process block 220 may exit via a sub-process block 340 and the substrate comprising one or more partially filled gap features may be subjected to the additional processes of exemplary gap fill process 100 of FIG. 1.

It should be appreciated that in some embodiments of the disclosure, the order of contacting of the substrate with the first vapor phase reactant (e.g., the molybdenum precursor) and the second vapor phase reactant (e.g., the reducing precursor) may be such that the substrate is first contacted with the second vapor phase reactant followed by the first vapor phase reactant. In addition, in some embodiments, the cyclical deposition phase 305 of exemplary process block 220 may comprise contacting the substrate with the first vapor phase reactant one or more times prior to contacting the substrate with the second vapor phase reactant one or more times. In addition, in some embodiments, the cyclical deposition phase 305 of exemplary process block 220 may comprise contacting the substrate with the second vapor phase reactant one or more times prior to contacting the substrate with the first vapor phase reactant one or more times.

In some embodiments the cyclical deposition process utilized for partially filling the one or more gap features may be a hybrid ALD/CVD or a cyclical CVD process. For example, in some embodiments, the growth rate of the ALD process may be low compared with a CVD process. One approach to increase the growth rate may be that of operating at a higher substrate temperature than that typically employed in an ALD process, resulting in some portion of a chemical vapor deposition process, but still taking advantage of the sequential introduction of precursors, such a process may be referred to as cyclical CVD. In some embodiments, a cyclical CVD process may comprise the introduction of two or more precursors into the reaction chamber wherein there may be a time period of overlap between the two or more precursors in the reaction chamber resulting in both an ALD component of the deposition and a CVD component of the deposition. For example, a cyclical CVD process may comprise the continuous flow of a one precursor and the periodic pulsing of a second precursor into the reaction chamber.

Once an initial molybdenum metal has been deposited, i.e., utilizing process block 220, and the molybdenum metal film partially fills the one or more gap features the cyclical deposition-etch phase 205 of exemplary gap fill process 100 (FIG. 2) may continue with the etch stage which may encompass a process block 230 comprising partially etching the molybdenum metal film.

In more detail, during the partial etching of the molybdenum metal film the substrate may be maintained at the same process temperature utilized in the deposition stage (i.e., process block 220), or alternatively during the partial etching of the molybdenum metal film the process temperature may be different to that utilized in the deposition stage. In some embodiments, the process temperature, i.e., the substrate temperature, during the etch stage (i.e., process block 230) may be less than approximately 800° C., or less than approximately 700° C., or less than approximately 600° C., or less than approximately 500° C., or less than approximately 400° C., or less than approximately 300° C., or even less than approximately 200° C. In some embodiments of the disclosure, the substrate temperature during the etch stage may be between 200° C. and 800° C., or between 300° C. and 700° C., or between 400° C. and 600° C., or between 525° C. and 575° C.

In addition to achieving a desired process temperature, i.e., a desired substrate temperature, during the partial etching of the molybdenum metal film the reaction chamber pressure may be regulated at the same pressure utilized in the deposition stage (i.e., process block 220), or alternatively during the partial etching of the molybdenum metal film the reaction chamber pressure may be different to that utilized in the deposition stage. In some embodiments, the pressure within the reaction chamber during the etch stage utilized for partially etching the molybdenum metal film may be regulated to a reaction chamber pressure of less than 300 Torr, or less than 200 Torr, or less than 100 Torr, or less than 50 Torr, or less than 25 Torr, or even less than 10 Torr. In some embodiments, the pressure within the reaction chamber during the etch stage of the cyclical deposition-etch phase 205 may be regulated at a pressure between 10 Torr and 300 Torr, or between 20 Torr and 80 Torr, or between 40 Torr and 50 Torr, or even equal to or greater than 20 Torr.

Upon obtaining a desired substrate temperature and reaction chamber pressure the process of partially etching the molybdenum metal film may comprise flowing an etchant gas into the reaction chamber and contacting the molybdenum metal film with the etchant gas. In some embodiments, the etchant gas may comprise a chloride etchant gas, such as, for example, chlorine vapor (Cl₂), or hydrochloric acid vapor (HCl). In particular embodiments of the disclosure, the chloride etchant gas may comprise a molybdenum chloride, such as, molybdenum pentachloride (MoCl₅), for example. Therefore, in some embodiments, the precursor utilized for the deposition of the molybdenum metal film and the etchant gas utilized to partially etch the molybdenum metal film both comprise a molybdenum component.

In some embodiments of the disclosure, partially etching the molybdenum metal film may comprise contacting the substrate and particularly the molybdenum metal film with a molybdenum chloride etchant gas for a time period of between about 0.1 seconds and about 30 seconds, between about 0.1 seconds and about 10 seconds, or between about 0.5 seconds and about 5.0 seconds, or even between 1.0 second and 2.0 seconds. In addition, during the partial etching of the molybdenum metal film with the molybdenum chloride etchant gas, the flow rate of the molybdenum chloride etchant gas may be less than 5000 sccm, or less than 1000 sccm, or less than 500 sccm, or even less than 100 sccm.

In some embodiments of the disclosure, the etch rate of the molybdenum metal film may be less than 10 Angstroms per second, or less than 8 Angstroms per second, or less than 6 Angstroms per second, or less than 4 Angstroms per second, or even less than 2 Angstroms per second. For example, the partial etching of the molybdenum metal film may comprise etching a thickness of the molybdenum metal film of less than 20 Angstroms, or less than 10 Angstroms, or even less than 5 Angstroms. In some embodiments, the molybdenum chloride etchant gas may preferentially etch the molybdenum metal film in proximity to the entrance of one or more gap features, thereby maintaining an opening to the one or more gap features for subsequent metal gap fill processes.

The etch stage of cyclical deposition-etch phase 205 may continue by purging the reaction chamber. For example, molybdenum chloride etchant gas and reaction byproducts (if any) may be removed from the surface of the substrate, e.g., by pumping with an inert gas. In some embodiments of the disclosure, the purge process may comprise a purge cycle wherein the substrate surface is purged for a time period of less than approximately 10.0 seconds, or less than approximately 5.0 seconds, or even less than approximately 2.0 seconds. Excess molybdenum chloride etchant gas and any possible reaction byproducts may be removed with the aid of a vacuum, generated by a pumping system in fluid communication with the reaction chamber.

The cyclic deposition-etch phase 205 of exemplary gap fill process 100 may continue with a decision gate 240, wherein the decision gate 240 is dependent on the thickness of the molybdenum metal film formed in the gap feature. For example, if the molybdenum metal film is formed at an insufficient thickness for the desired gap feature, then the cyclical deposition-etch phase 205 may be repeated by returning to the process block 220 and continuing through a further cyclical deposition-etch cycle, wherein a unit cyclical deposition-etch cycle may comprise partially filing the one or more gap features with a molybdenum metal film (process block 220), purging the reaction chamber, partially etching the molybdenum metal film (process block 230), and again purging the reaction chamber. A unit cycle of cyclical deposition-etch phase 205 may be repeated one or more times until a desired thickness of a molybdenum metal film is formed within the one or more gap features, wherein the desired thickness of the molybdenum metal film formed by one or repetitions of the cyclical deposition-etch phase may be dependent on the aspect ratio of the gap feature to be filled. In some embodiments, the cyclical deposition-etch phase 205 may be repeated until the one or more gap features are at least 80 percent, or 90 percent, or even 95 percent filled with a molybdenum metal film.

Once the molybdenum metal film has been formed to the desired thickness the cyclical deposition-etch phase 205 may halt and exemplary gap fill process 100 may continue by means of a process block 250 comprising filling the one or more gap features with a molybdenum metal film by a second cyclical deposition process.

In more detail, the cyclical deposition-etch process 205 partially fills the one or more gap features with a molybdenum metal film and a second deposition process comprising a second cyclical deposition process may be utilized to completely fill the one or more gap features with the molybdenum metal film. The second deposition process (process block 250) may comprise filling the one or more gap features with a molybdenum metal film by performing at least one unit cycle of a second cyclical deposition process. In some embodiment, the second cyclical deposition process may be the same as the first cyclical deposition process utilized to partially fill the one or more gap features with a molybdenum metal film (i.e., process block 220). Therefore the process block 250 is described in brief with reference to FIG. 3, as the process has been previously described with reference to the process block 220.

Therefore, in more detail, the substrate including the partially filled gap features may be disposed in a reaction chamber configured for at least one of an atomic layer deposition process and/or a cyclical chemical vapor deposition process. In some embodiments, the second cyclical deposition process may comprise an atomic layer deposition process or a cyclical chemical vapor deposition process.

In some embodiments, the process temperature utilized for the second cyclical deposition cycle may be the same as that utilized for the first cyclical deposition process. For example, the process temperature, i.e., the substrate temperature, during the second cyclical deposition process may be less than approximately 800° C., or less than approximately 700° C., or less than approximately 600° C., or less than approximately 500° C., or less than approximately 400° C., or less than approximately 300° C., or even less than approximately 200° C. In some embodiments of the disclosure, the substrate temperature during the second cyclical deposition process may be between 200° C. and 800° C., or between 300° C. and 700° C., or between 400° C. and 600° C., or even between 525° C. and 575° C.

In addition to achieving a desired process temperature, i.e., a desired substrate temperature, during the second cyclical deposition process the reaction chamber pressure may be regulated at the same pressure utilized in the first cyclical deposition stage (i.e., process block 220). Therefore, in some embodiments, the pressure within the reaction chamber during the second cyclical deposition process for filling the one or more gap features with the molybdenum metal film may be regulated to a reaction chamber pressure of less than 300 Torr, or less than 200 Torr, or less than 100 Torr, or less than 50 Torr, or less than 25 Torr, or even less than 10 Torr. In some embodiments, the pressure within the reaction chamber during the second cyclical deposition process may be regulated at a pressure between 10 Torr and 300 Torr, or between 20 Torr and 80 Torr, or between 40 Torr and 50 Torr, or even equal to or greater than 20 Torr.

In some embodiment of the disclosure, filling the one or more gap features with molybdenum metal film by performing at least one unit cycle of a second cyclical deposition process may comprise performing at least one unit cycle of cyclical deposition phase 305 of FIG. 3, i.e., contacting the substrate with a molybdenum halide precursor (sub-process block 310), purging the reaction chamber, contacting the substrate with a reducing agent precursor (sub-process block 320), and purging the reaction chamber. The molybdenum halide precursor may comprise all the molybdenum halide precursors as previously described, and in particular embodiments, the molybdenum halide precursor may comprise molybdenum (IV) dichloride dioxide (MoO₂Cl₂). The reducing agent precursor may comprise all the reducing agent precursors as previously described, and in particular embodiments, the reducing agent precursor may comprise molecular hydrogen (H₂).

The second cyclical deposition process 250 may continue be means of a decision gate 340, wherein the decision gate 340 is dependent on the thickness of the molybdenum metal film formed in the one or more gap features. For example, if the molybdenum metal film is deposited at an insufficient thickness to completely fill the one or more gap features, then the cyclical deposition phase 305 may be repeated by returning to the sub-process block 310 and continuing through a further deposition cycle, wherein a unit deposition cycle may comprise contacting the substrate with a molybdenum halide precursor (sub-process block 310), purging the reaction chamber, contacting the substrate with a reducing agent precursor (sub-process block 320), and again purging the reaction chamber. A unit deposition cycle of cyclical deposition phase 305 may be repeated one or more times until the one or more gap features is completely filled with a molybdenum metal film. Once the molybdenum metal film has completely filled the one or more gap features the exemplary atomic layer deposition process block 250 may exit via a sub-process block 340 and the substrate comprising one or more filled gap features may be subjected to the additional processes of exemplary gap fill process 100 of FIG. 1. For example, the final process block of exemplary gap fill process 100 may comprise process block 260 which exits the gap fill process, the substrate with the one or more molybdenum filled gap features may then be subjected to further processes to complete the desired semiconductor device structure.

In some embodiments of the disclosure, the molybdenum metal films formed may have a thickness from about 20 Angstroms to about 250 Angstroms, or about 50 Angstroms to about 200 Angstroms, or even about 100 Angstroms to about 150 Angstroms. In some embodiments, the molybdenum metal films formed according to some of the embodiments described herein may have a thickness greater than about 20 Angstroms, or greater than about 30 Angstroms, or greater than about 40 Angstroms, or greater than about 50 Angstroms, or greater than about 60 Angstroms, or greater than about 100 Angstroms, or greater than about 250 Angstroms, or greater than about 500 Angstroms, or greater. In some embodiments the molybdenum metal films formed according to some of the embodiments described herein may have a thickness of less than about 250 Angstroms, or less than about 100 Angstroms, or less than about 50 Angstroms, or less than about 25 Angstroms, or less than about 10 Angstroms, or even less than about 5 Angstroms.

In some embodiments of the disclosure, the gap fill molybdenum metal film may comprise a crystalline film. In some embodiments, the gap fill molybdenum metal film may comprise a polycrystalline film wherein the plurality of crystalline grains comprising the polycrystalline molybdenum metal film may have a grain size greater than 100 Angstroms.

In some embodiments of the disclosure, the molybdenum metal films formed by the methods disclosure herein may be utilized to fill one or more vertical gap features and/or one or more horizontal gap features.

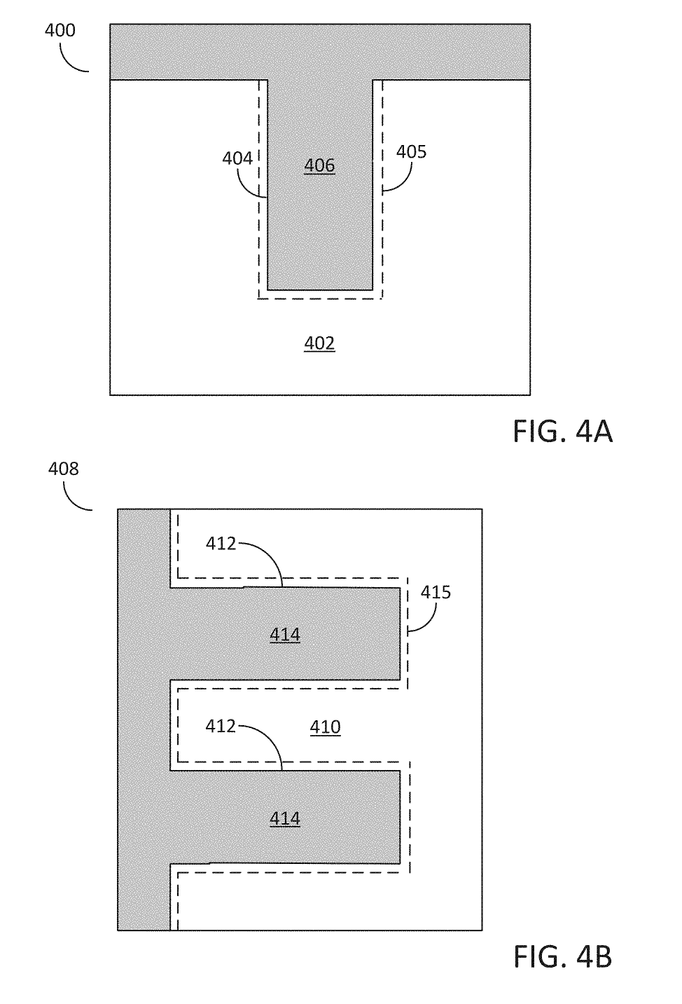

For example, FIG. 4A illustrates a semiconductor device structure 400 which comprises a substrate 402 with a vertical high aspect ratio gap feature 404, wherein the aspect ratio (height:width) may be greater than 2:1, or greater than 5:1, or greater than 10:1, or greater than 25:1, or greater than 50:1, or even greater than 100:1, wherein “greater than” in this particular example refers to a greater distance in the height of the gap feature.

The gap fill methods disclosure herein may be utilized to form a molybdenum metal film directly over the surface of the vertical high aspect ratio feature 404, as illustrated by a molybdenum metal film 406. In some embodiments of the disclosure, the surface of the vertical high aspect ratio feature may comprise a dielectric material and therefore the molybdenum gap fill metal 406 may be disposed directly on the dielectric materials surface. In alternative embodiments, the vertical high aspect ratio feature 404 may be lined with a liner material 405 which may comprise a metallic material, such as, for example, a pure metal, a metal nitride, a metal carbide, a metal boride, or mixtures thereof. Therefore in some embodiments, the surface of the vertical high aspect ratio feature may comprise a metallic material and therefore the molybdenum gap fill metal 406 may be disposed directly on the metallic material surface.

In some embodiments, the step coverage of the molybdenum metal film directly on the vertical high aspect ratio gap feature may be equal to or greater than about 50%, or greater than about 80%, or greater than about 90%, or greater than about 95%, or greater than about 98%, or about 99% or greater.

As a non-limiting example, the semiconductor device structure 400 may represent a partially fabricated CMOS logic device wherein the substrate 402 may comprise an interlayer dielectric and the molybdenum metal film 406 may comprise a metal gap-fill for providing electrical connection to one or more transistor structures (not shown). As illustrated in FIG. 4A, the molybdenum metal film 406 may be in direct contact with the dielectric material 402 without the need for an intermediate barrier layer material, thereby reducing the overall effective electrical resistivity of the semiconductor device structure 400.

In some embodiments, the molybdenum metal film may be utilized as a gap-fill metallization and the molybdenum metal film may fill the gap features, i.e., a vertical high aspect ratio gap feature, without the formation of a seam, wherein a seam may refer to a line or one or more voids formed by the abutment of edges formed in a gap fill material, and the seam can be confirmed by using scanning transmission electron microscopy (STEM) or transmission electron microscopy (TEM), wherein if observations reveal a clear vertical line or one or more vertical voids in the gap fill material, a seam is present.

As a further non-limiting example, FIG. 4B illustrates a semiconductor device structure 408 which comprises a substrate 410 with one or more horizontal high aspect ratio gap features 412, wherein the aspect ratio (height:width) may be greater than 1:2, or greater than 1:5, or greater than 1:10, or greater than 1:25, or greater than 1:50, or even greater than 1:100, wherein this particular example the term “greater than” refers to a greater distance in the width of the gap feature. The deposition methods disclosure herein may be utilized to form a molybdenum metal film directly over the surface of the horizontal high aspect ratio gap feature 412, as illustrated by a molybdenum metal film 414. In some embodiments, the substrate 410 and the surface of the horizontal gap feature may comprise a dielectric material and therefore the molybdenum gap fill metal may be disposed directly on the dielectric surface. In alternative embodiments, the substrate 410 may be lined with an optional liner material 415 which may comprise a metallic material and therefore the molybdenum gap fill metal 414 may be disposed directly on the metallic surface. In some embodiments, the step coverage of the molybdenum metal film directly on the horizontal high aspect ratio gap feature may be equal to or greater than about 50%, or greater than about 80%, or greater than about 90%, or greater than about 95%, or greater than about 98%, or about 99% or greater.

As a non-limiting example embodiment, the semiconductor device structure 408 may represent a portion of a partially fabricated memory device wherein the substrate 412 may comprise an aluminum oxide (Al₂O₃) and the molybdenum metal film 406 may comprise a metal gate structure.

As with the vertical gap-fill processes, the molybdenum metal film may be utilized as a gap-fill metallization for horizontal high aspect ratio features without the formation of a seam, as previously described.

In some embodiments of the disclosure, the molybdenum gap fill metal films formed according to the embodiments of the disclosure may comprise low electrical resistivity molybdenum metal films. For example, in some embodiments, the molybdenum metal films may have an electrical resistivity of less than 3000 μΩ-cm, or less than 1000 μΩ-cm, or less than 500 μΩ-cm, or less than 200 μΩ-cm, or less than 100 μΩ-cm, or less than 50 μΩ-cm, or less than 25 μΩ-cm, or less than 15 μΩ-cm, or even less than 10 μΩ-cm. As a non-limiting example, a molybdenum metal film may be utilized to fill one or more gap features to a thickness of approximately less than 100 Angstroms and the molybdenum metal film may exhibit an electrical resistivity of less than 35 μΩ-cm. As a further non-limiting example, a molybdenum metal film may be utilized to fill one or more gap features to a thickness of less than 200 Angstroms and the molybdenum metal film may exhibit an electrical resistivity of less than 25 μΩ-cm.

In some embodiments of the disclosure, the gap fill methods may further comprise forming a molybdenum metal film with a low atomic percentage (atomic-%) of impurities. For example, the molybdenum metal films of the current disclosure may comprise an impurity concentration of less than 5 atomic-%, or less than 2 atomic-%, or even less than 1 atomic-%. In some embodiments, the impurities disposed within the molybdenum metal film may comprise at least oxygen and chlorine.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

What is claimed is:

1. A method for filling a gap feature on a substrate surface, the method comprising:
providing a substrate comprising one or more gap features into a reaction chamber;
partially filling the one or more gap features with a molybdenum metal film by a cyclical deposition-etch process, wherein a unit cycle of the cyclical deposition-etch process comprises:
partially filing the one or more gap features with a molybdenum metal film by performing at least one unit cycle of a first cyclical deposition process; and
partially etching the molybdenum metal film; and
filling the one or more gap features with a molybdenum metal film by performing at least one unit cycle of a second cyclical deposition process.

2. The method of claim 1, further comprising heating the substrate to a substrate temperature of between 300° C. and 700° C.

3. The method of claim 1, further comprising regulating the pressure within the reaction chamber to greater than 20 Torr.

4. The method of claim 1, wherein a unit cycle of the first and second cyclical deposition process comprises:
contacting the substrate with a first vapor phase reactant comprising a molybdenum halide precursor; and
contacting the substrate with a second vapor phase reactant comprising a reducing agent precursor.

5. The method of claim 4, wherein the molybdenum halide precursor comprises a molybdenum chalcogenide halide.

6. The method of claim 5, wherein the molybdenum chalcogenide halide comprises a molybdenum oxyhalide selected from the group comprising: a molybdenum oxyhalide, a molybdenum oxyiodide, or a molybdenum oxybromide.

7. The method of claim 6, wherein the molybdenum oxychloride comprises molybdenum (IV) dichloride dioxide (MoO₂Cl₂).

8. The method of claim 4, wherein the reducing agent precursor comprises at least one of molecular hydrogen (H₂), atomic hydrogen (H), forming gas (H₂+N₂), ammonia (NH₃), hydrazine (N₂H₄), a hydrazine derivative, a hydrogen based plasma, hydrogen radicals, hydrogen excited species, an alcohol, an aldehyde, a carboxylic acid, a borane, an amine, or a silane.

9. The method of claim 4, wherein the first and second cyclical deposition process comprise an atomic layer deposition process.

10. The method of claim 4, wherein the first and second cyclical deposition process comprise a cyclical chemical vapor deposition process.

11. The method of claim 1, wherein partially etching the molybdenum film further comprises contacting the molybdenum metal film with a molybdenum halide etchant.

12. The method of claim 11, wherein the molybdenum halide etchant comprises molybdenum pentachloride (MoCl₅).

13. The method of claim 1, wherein the one or more gap feature comprises a substantially vertical gap feature with an aspect ratio of greater than 2:1.

14. The method of claim 1, wherein the one or more gap features comprises a substantially horizontal gap feature with an aspect ratio of greater than 1:2.

15. The method of claim 1, wherein the molybdenum metal film fills the one or more gap features without the formation of a seam.

16. The method of claim 4, wherein the cyclical deposition process comprises depositing the molybdenum metal film directly on a dielectric surface.

17. The method of claim 4, wherein the cyclical deposition process comprises depositing the molybdenum metal film directly on a metallic surface.

18. A semiconductor device structure comprising one or more gap features filled with a molybdenum metal film by the method of claim 1.
